(19) United States
(12) Patent Application Publication
(10) Pub. No.: US 2008/0119017 A1
(43) Pub. Date: May 22, 2008

(54) Method for manufacturing thin film transistor using differential photo-resist developing

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/985,983

(22) Filed: Nov. 19, 2007

(30) Foreign Application Priority Data
Nov. 17, 2006 (CN) 200610156920.8

(51) Int. Cl. H01L 21/00

(52) U.S. Cl. 438/151; 257/E21.001

(57) ABSTRACT

An exemplary method for manufacturing a thin film transistor includes: forming at least two photo-resist layers on a substrate, a developing speed of an upper one of the photo-resist layers being less than that of each photo-resist layer below said upper one of the photo-resist layers; exposing and developing the photo-resist layers, thereby forming residual photo-resist layers having a reduced width from top to bottom; subsequently depositing a plurality of metal layers on the substrate having the residual photo-resist layers; removing the residual photo-resist layers and the metal layers deposited on the photo-resist layers, thereby forming a gate electrode which includes residual metal layers and which has an increased width from top to bottom; forming a gate insulation layer on the substrate having the gate electrode; forming a semiconductor layer on the gate insulation layer; and forming a source electrode and a drain electrode on the semiconductor layer.

### FIELD OF THE INVENTION

The present invention relates to a method for manufacturing a thin film transistor (TFT), the method including developing different photo-resist layers at different speeds.

### GENERAL BACKGROUND

Liquid crystal displays (LCDs) are in wide use as display devices. An LCD is capable of reducing the overall size, weight and thickness of an electronic apparatus in which it is employed. An LCD generally includes a first substrate having a plurality of TFTs thereon, a second substrate parallel to the first substrate, and a liquid crystal layer sandwiched between the first and second substrates.

Referring to FIG. 10, a typical TFT (not labeled) on the first substrate of an LCD includes a glass substrate 110, a gate electrode 120 on the substrate 110, a gate insulation layer 130 on the gate electrode 120 and the substrate 110, a semiconductor layer 140 on the gate insulation layer 130, and a source electrode 150 and a drain electrode 160 on the gate insulation layer 130 and the semiconductor layer 140. The gate electrode 120 is generally made from copper, which has relatively weak adhesion with the substrate 110. This may result in breaking away of the gate electrode 120 from the substrate 110. When this happens, the reliability of the TFT is liable to be impaired. Moreover, the TFT generally has weak heat dissipation. Therefore a temperature of the TFT may be unduly high when the TFT works for a long time. When this happens, copper ions may be released from the gate electrode 120, and may be driven into the gate insulation layer 130 or even the semiconductor layer 140. This phenomenon is known as copper pollution. Thus, functioning of the TFT may be impaired or even ruined altogether.

To overcome the above-described problems, the following method for manufacturing a gate electrode of a TFT has been developed. Referring to FIG. 11, the method includes: step S1, sequentially depositing three metal layers and a photo-resist layer on a substrate; step S2, exposing and developing the photo-resist layer; step S3, etching the three metal layers; and step S4, removing the residual photo-resist layer.

Referring to FIG. 12, in step S1, a first metal layer 220, a second metal layer 230, a third metal layer 240, and a photo-resist layer 250 are sequentially deposited on a substrate 210. The substrate 210 is transparent, and acts as a carrier of other elements. The first and third metal layers 220, 240 are made from titanium, which can resist diffusion of copper ions. The second metal layer 230 is made from copper.

Referring to FIG. 13, in step S2, the photo-resist layer 250 is exposed and developed.

Referring to FIG. 14, in step S3, using the residual photo-resist layer 250 as a mask, the first, second, and third metal layers 220, 230, 240 are etched, thereby forming a gate electrode 20.

Referring to FIG. 15, in step S4, the residual photo-resist layer 250 is removed, with the gate electrode 20 remaining on the substrate 210.

After the gate electrode 20 is formed, the remainder of the TFT is subsequently formed. Referring to FIG. 16, in a first subsequent step, a gate insulation layer 290 is formed on the gate electrode 20 and the substrate 210.

In the above-described method, an etching speed of the second metal layer 230 is less than that of the first and third metal layers 220, 240, due to characteristics of the respective materials thereof. That is, the residual second metal layer 230 may outwardly extend beyond side edges of the residual first and third metal layers 220, 240, as is shown in FIG. 14. Referring also to FIG. 16, a hole 270 is thus formed between the gate electrode 20 and the gate insulation layer 130, which hole 270 may result in breakage of the gate insulation layer 130. When this happens, the subsequently formed source and drain electrodes 150, 160 may correspondingly break. Thus, the functioning of the TFT may still be impaired or even ruined altogether.

What is needed, therefore, is a method for manufacturing a TFT which can overcome the above-described deficiencies.

### SUMMARY

In an exemplary embodiment, a method for manufacturing a thin film transistor includes: forming at least two photo-resist layers on a substrate, a developing speed of an upper one of the photo-resist layers being less than that of each photo-resist layer below said upper one of the photo-resist layers; exposing and developing the photo-resist layers, thereby forming residual photo-resist layers having a reduced width from top to bottom; subsequently depositing a plurality of metal layers on the substrate having the residual photo-resist layers; removing the residual photo-resist layers and the metal layers deposited on the photo-resist layers, thereby forming a gate electrode which includes residual metal layers and which has an increased width from top to bottom; forming a gate insulation layer on the substrate having the gate electrode; forming a semiconductor layer on the gate insulation layer; and forming a source electrode and a drain electrode on the semiconductor layer.

Other novel features, advantages and aspects will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of at least one embodiment of the present method. In the drawings, like reference numerals designate corresponding parts throughout various views, and all the views are schematic.

FIG. 1 is a flowchart summarizing a method for manufacturing a TFT according to an exemplary embodiment of the present invention.

FIG. 2 is a schematic, side cross-sectional view relating to a step of forming at least two photo-resist layers on a substrate, according to the method of FIG. 1.

FIG. 3 is a schematic, side cross-sectional view relating to a next step of exposing and developing the photo-resist layers, thereby forming residual photo-resist layers having reduced width from top to bottom, according to the method of FIG. 1.

FIG. 4 is a schematic, side cross-sectional view relating to a next step of depositing a plurality of metal layers on the substrate having the residual photo-resist layers, according to the method of FIG. 1.

FIG. 5 is a schematic, side cross-sectional view relating to a next step of removing the residual photo-resist layers and the metal layers deposited on the photo-resist layers, thereby forming a gate electrode which includes the residual metal layers and which has an increased width from top to bottom, according to the method of FIG. 1.

FIG. 6 is a schematic, side cross-sectional view relating to a next step of depositing a gate insulation layer on the substrate, according to the method of FIG. 1.

FIG. 7 is a schematic, side cross-sectional view relating to a next step of forming a semiconductor layer on the gate insulation layer, according to the method of FIG. 1.

FIG. 8 is a schematic, side cross-sectional view relating to a next step of forming a source electrode and a drain electrode on the semiconductor layer, according to the method of FIG. 1.

FIG. 9 is a schematic, side cross-sectional view relating to a next step of depositing a passivation layer and forming a connecting hole, according to the method of FIG. 1.

FIG. 10 is schematic, side cross-sectional view of a conventional TFT.

FIG. 11 is a flowchart summarizing a conventional method for manufacturing a gate electrode of the TFT of FIG. 10.

FIG. 12 is a schematic, side cross-sectional view relating to a step of depositing three metal layers and a photo-resist layer on a substrate, according to the method of FIG. 11.

FIG. 13 is a schematic, side cross-sectional view relating to a next step of exposing and developing the photo-resist layer, according to the method of FIG. 11.

FIG. 14 is a schematic, side cross-sectional view relating to a next step of etching the three metal layers, according to the method of FIG. 11.

FIG. 15 is a schematic, side cross-sectional view relating to a next step of removing the residual photo-resist layer and thereby obtaining the gate electrode, according to the method of FIG. 11.

FIG. 16 is a schematic, side cross-sectional view showing a gate insulation layer formed on the gate electrode and the substrate of FIG. 15.

### DETAILED DESCRIPTION OF PREFERRED EMBODIMENTS

Reference will now be made to the drawings to describe preferred and exemplary embodiments of the present invention in detail.

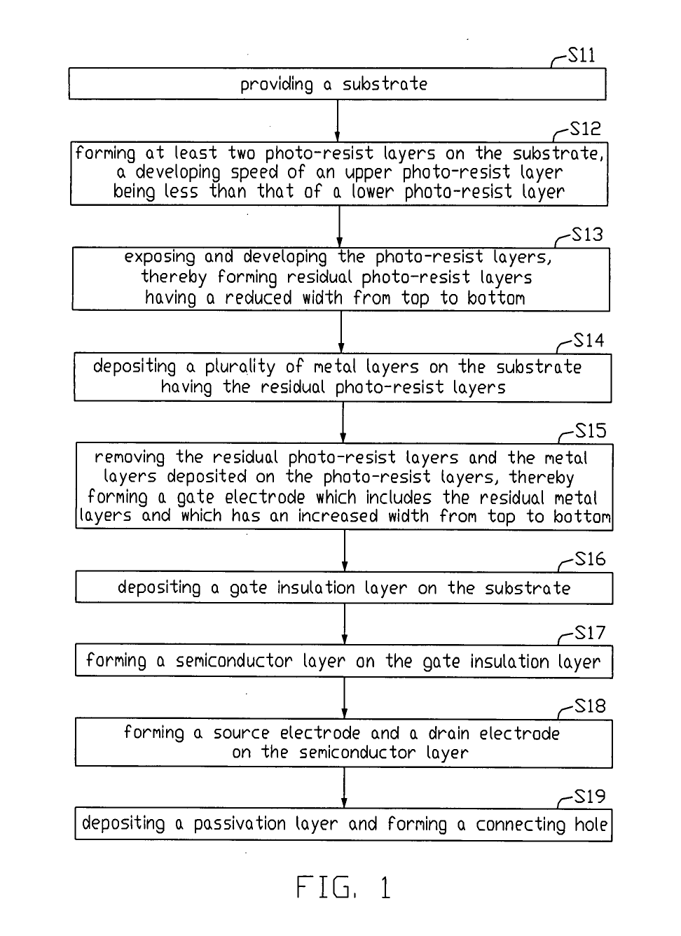

Referring to FIG. 1, a flowchart summarizing a method for manufacturing a TFT according to an exemplary embodiment of the present invention is shown. The method includes: step S11, providing a substrate; step S12, forming at least two photo-resist layers on the substrate, a developing speed of an upper photo-resist layer being less than that of a lower photo-resist layer; step S13, exposing and developing the photo-resist layers, thereby forming residual photo-resist layers having a reduced width from top to bottom; step S14, depositing a plurality of metal layers on the substrate having the residual photo-resist layers; step S15, removing the residual photo-resist layers and the metal layers deposited on the photo-resist layers, thereby forming a gate electrode which includes the residual metal layers and has an increased width from top to bottom; step S16, depositing a gate insulation layer on the substrate; step S17, forming a semiconductor layer on the gate insulation layer; step S18, forming a source electrode and a drain electrode on the semiconductor layer; and step S19, depositing a passivation layer and forming a connecting hole.

In step S11, a substrate 41 is provided. The substrate 41 acts as a carrier of other elements. The substrate 41 is transparent and insulating, and is generally made from glass or quartz.

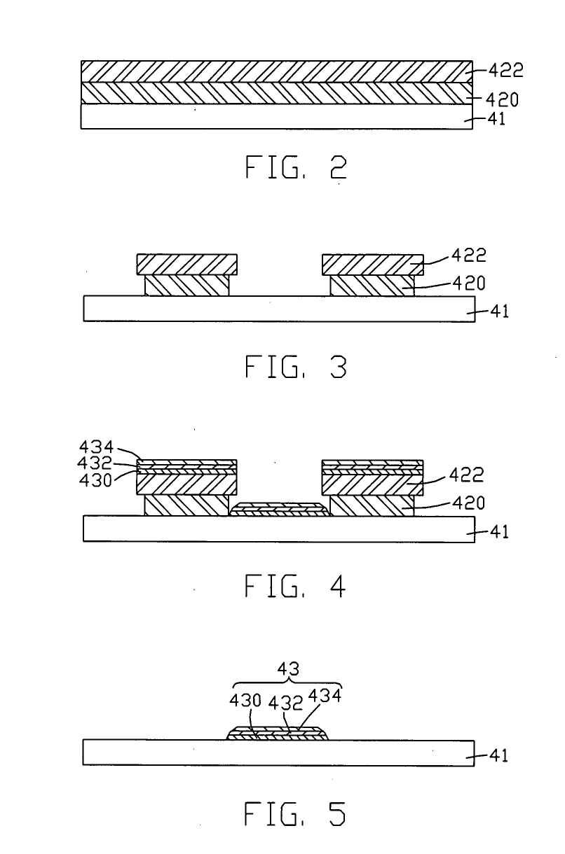

In step S12, as shown in FIG. 2, a first photo-resist layer 420 and a second photo-resist layer 422 are formed on the substrate 41, wherein a developing speed of the second photo-resist layer 422 is less than that of the first photo-resist layer 420. In the illustrated embodiment, the first and second photo-resist layers 420, 422 are positive photo-resist layers, and have a same thickness. The first and second photo-resist layers 420, 422 can be formed by a spin coating method or a spray coating method.

Referring to FIG. 3, in step S13, the first and second photo-resist layers 420, 422 are exposed and developed, thereby forming residual photo-resist layers 420, 422 having a reduced width from top to bottom. A mask (not shown) having a light-transmitting pattern is aligned with the first and second photo-resist layers 420, 422. Portions of the first and second photo-resist layers 420, 422 corresponding to the light-transmitting pattern are subsequently exposed to light passing through the mask. The exposed first and second photo-resist layers 420, 422 are further developed by coating developing solutions thereon. Because the developing speed of the second photo-resist layer 422 is less than that of the first photo-resist layer 420, the residual first and second photo-resist layers 420, 422 have a reduced width from top to bottom. That is, the residual first photo-resist layer 420 has a width less than that of the residual second photo-resist layer 422.

Referring to FIG. 4, in step S14, a first metal layer 430, a second metal layer 432, and a third metal layer 434 are subsequently deposited on the substrate 41 having the residual first and second photo-resist layers 420, 422. The first metal layer 430 can be strongly adhered to the substrate 41, and can be made from a material selected from the group consisting of titanium, chromium, tungsten, molybdenum, molybdenum nitride, tantalum nitride, and titanium nitride. The second metal layer 432 is made from a material having low electrical resistance, such as copper. The third metal layer 434 can be a material selected from the group consisting of titanium, chromium, tungsten, molybdenum, molybdenum nitride, tantalum nitride, and titanium nitride, such that the third metal layer 434 can resist diffusion of copper ions. The first and third metal layers 430, 434 can be made from different materials or the same material. The first, second, and third metal layers 430, 432, 434 can be deposited by a physical vapor deposition (PVD) method. A total thickness of the first, second, and third metal layers 430, 432, 434 is preferably one third of a total thickness of the residual first and second photo-resist layers 420, 422. That is, the total thickness of the first, second, and third metal layers 430, 432, 434 is less than the thickness of the residual first photo-resist layer 420. The first, second, and third metal layers 430, 432, 434 deposited on bare areas of the substrate 41 which are located between portions of the stacked residual first and second photo-resist layers 420, 422. Thus, the first, second, and third metal layers 430, 432, 434 between the residual first and second photo-resist layers 420, 422 have increasing width from top to bottom, and have smoothly inclined edges.

Referring to FIG. 5, in step S15, the residual first and second photo-resist layers 420, 422 and the first, second, and third metal layers 430, 432, 434 deposited on the residual first and second photo-resist layers 420, 422 are removed, thereby forming a gate electrode 43 which includes the residual first, second, and third metal layers 430, 432, 434 and which has an increased width from top to bottom. The substrate 41 having the residual first and second photo-resist layers 420, 422 and the first, second, and third metal layers 430, 432, 434 is immersed in a stripping solution, such as acetone. The first, second, and third metal layers 430, 432, 434 deposited on the residual second photo-resist layer 422 are stripped off with the residual first and second photo-resist layers 420, 422. The residual first, second, and third metal layers 430, 432, 434 on the substrate 41 constitute the gate electrode 43. The gate electrode 43 has an increasing width from top to bottom, and has smoothly inclined edges.

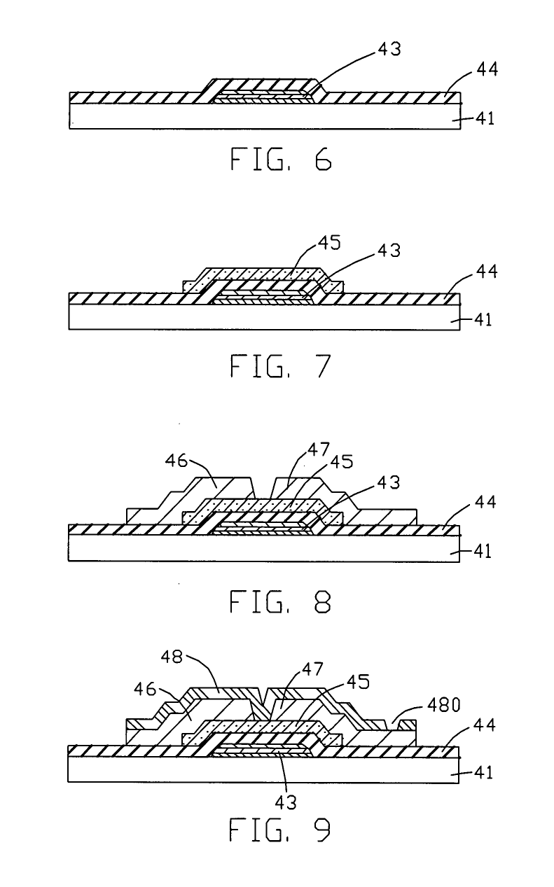

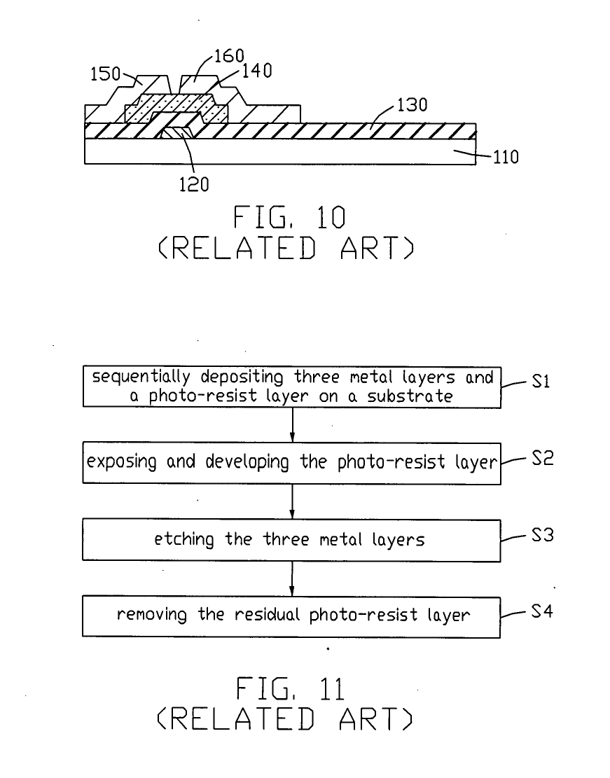

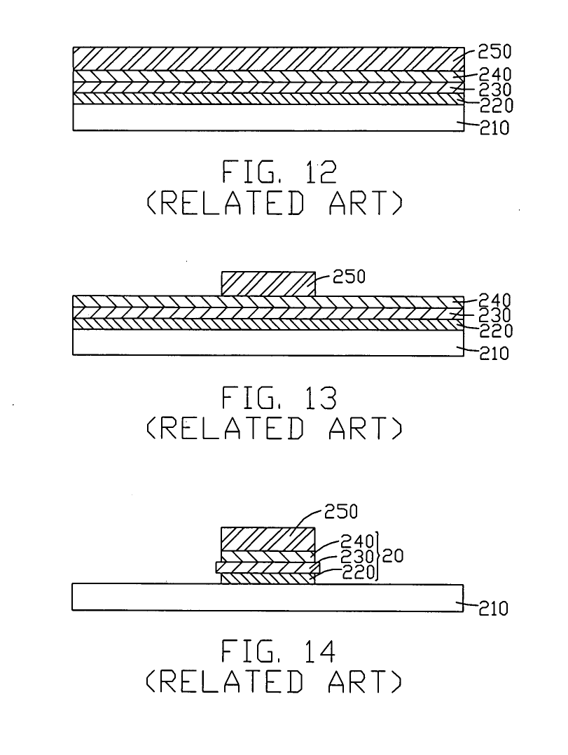

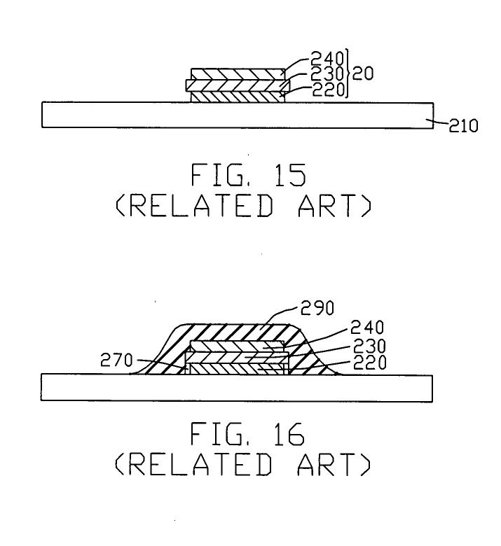

Referring to FIG. 6, in step S16, a gate insulation layer 44 is deposited on the substrate 41 having the gate electrode 43. The gate insulation layer 44 is made from silicon nitride, and can be deposited by a chemical vapor deposition (CVD) method.

Referring to FIG. 7, in step S17, a semiconductor layer 45 is formed on the gate insulation layer 44. A semiconductor material and a third photo-resist layer (not shown) are deposited on the gate insulation layer 44. The third photo-resist layer is exposed and developed. Using the residual third photo-resist layer as a mask, the semiconductor material is wet etched, thereby forming the semiconductor layer 45 on the gate insulation layer 44.

Referring to FIG. 8, in step S18, a source electrode 46 and a drain electrode 47 are formed on the semiconductor layer 45. A material of the source and drain electrodes 46, 47 and a fourth photo-resist layer (not shown) are deposited on the semiconductor layer 45 and the gate insulation layer 44 in sequence. The fourth photo-resist layer is exposed and developed. Using the residual fourth photo-resist layer as a mask, the material of the source and drain electrodes 46, 47 is wet etched, thereby forming the source electrode 46 and the drain electrode 47.

Referring to FIG. 9, in step S19, a passivation layer 48 with a connecting hole 480 is formed. The passivation layer 48 and a fifth photo-resist layer (not shown) are deposited on the gate insulation layer 44, the source electrode 46, and the drain electrode 47. The fifth photo-resist layer is exposed and developed. Using the residual fifth photo-resist layer as a mask, the passivation layer 48 is etched, thereby forming the connecting hole 480. The drain electrode 47 is exposed through the connecting hole 480. Thus, the TFT is obtained.

In the above-described method, the developing speed of the second photo-resist layer 422 is less than that of the first photo-resist layer 420, which helps to form the gate electrode 43 that has the width smoothly increasing from top to bottom. Therefore, the method for manufacturing the TFT can prevent the unwanted creation of holes between the gate electrode 43 and the gate insulation layer 44. Thus, the stability of the gate insulation layer 44, the source electrode 46, and the drain electrode 47 is improved, and the reliability of the TFT is correspondingly improved.

Further or alternative embodiments may include the following. In one example, the plural photo-resist layers formed on the substrate 41 can include three or more photo-resist layers. In another example, the first and second photo-resist layers 420, 422 can be negative photo-resist layers. In such case, the developing speeds of the first and second photo-resist layers 420, 422 increase from top to bottom. In a further example, the plural metal layers can include four or more metal layers.

It is believed that the present embodiments and their advantages will be understood from the foregoing description, and it will be apparent that various changes may be made thereto without departing from the spirit or scope of the invention or sacrificing all of its material advantages, the examples hereinbefore described merely being preferred or exemplary embodiments of the invention.

What is claimed is:

1. A method for manufacturing a thin film transistor, the method comprising:
forming at least two photo-resist layers on a substrate, a developing speed of an upper one of the photo-resist layers being less than that of each photo-resist layer below said upper one of the photo-resist layers;
exposing and developing the photo-resist layers, thereby forming residual photo-resist layers having a reduced width from top to bottom;
subsequently depositing a plurality of metal layers on the substrate having the residual photo-resist layers;
removing the residual photo-resist layers and the metal layers deposited on the photo-resist layers, thereby forming a gate electrode which comprises residual metal layers and which has an increased width from top to bottom;
forming a gate insulation layer on the substrate having the gate electrode;
forming a semiconductor layer on the gate insulation layer; and
forming a source electrode and a drain electrode on the semiconductor layer.

2. The method as claimed in claim 1, wherein the at least two photo-resist layers have a same thickness.

3. The method as claimed in claim 1, wherein the plurality of metal layers comprise a first metal layer, a second metal layer, and a third metal layer, arranged in that order from bottom to top.

4. The method as claimed in claim 3, wherein the first metal layer is strongly adhered to the substrate.

5. The method as claimed in claim 3, wherein the first and third metal layers are made from the same material.

6. The method as claimed in claim 3, wherein the first and third metal layers are made from a material selected from the group consisting of: titanium, chromium, tungsten, molybdenum, molybdenum nitride, tantalum nitride, and titanium nitride.

7. The method as claimed in claim 3, wherein the second metal layer has low electrical resistance.

8. The method as claimed in claim 3, wherein the second metal layer is made from copper.

9. The method as claimed in claim 1, wherein the plurality of metal layers are deposited by a physical vapor deposition method.

10. The method as claimed in claim 1, wherein a total thickness of the plurality of metal layers is one third of a total thickness of the residual at least two photo-resist layers.

11. The method as claimed in claim 1, wherein the plurality of metal layers have increasing widths in that order from top to bottom.

12. The method as claimed in claim 11, wherein the plurality of metal layers have smoothly inclined edges.

13. The method as claimed in claim 1, further comprising forming a passivation layer on the source and drain electrodes and forming a connecting hole in the passivation.

14. The method as claimed in claim 13, wherein the drain electrode is exposed through the connecting hole.

15. A method for manufacturing a thin film transistor, the method comprising:
forming at least two photo-resist layers on a substrate, the at least two photo-resist layers having progressively reduced developing speed from a photo-resist layer adjacent to the substrate to a photo-resist layer farthest from the substrate;
exposing and developing the photo-resist layers, thereby forming residual photo-resist layers having increased width in a direction away from the substrate;
depositing a plurality of metal layers on the substrate having the residual photo-resist layers;
removing the residual photo-resist layers and the metal layers deposited on the photo-resist layers, thereby forming a gate electrode which comprises residual metal layers and which has decreased width in a direction away from the substrate;
forming a gate insulation layer on the substrate having the gate electrode;
forming a semiconductor layer on the gate insulation layer; and
forming a source electrode and a drain electrode on the semiconductor layer.

16. The method as claimed in claim 15, wherein the plurality of metal layers comprise a first metal layer, a second metal layer, and a third metal layer, arranged in that order from bottom to top.

17. The method as claimed in claim 16, wherein the first and third metal layers are made from the same material.

18. The method as claimed in claim 16, wherein the first and third metal layers are made from a material selected from the group consisting of: titanium, chromium, tungsten, molybdenum, molybdenum nitride, tantalum nitride, and titanium nitride.

19. The method as claimed in claim 15, wherein the plurality of metal layers have increasing widths in that order from top to bottom.

20. The method as claimed in claim 19, wherein the plurality of metal layers have smoothly inclined edges.
